(19) United States
(12) Patent Application Publication
(10) Pub. No.: US 2023/0040718 A1
(43) Pub. Date: Feb. 9, 2023

(54) RACK MOUNTING ADAPTER WITH AIRFLOW MANAGEMENT

(71) Applicant: CommScope Technologies LLC, Hickory, NC (US)

(72) Inventors: Craig Steven Mason, Forest, VA (US); Neil Townsend Hobbs, Forest, VA (US)

(73) Assignee: CommScope Technologies LLC, Hickory, NC (US)

(21) Appl. No.: 17/879,578

(22) Filed: Aug. 2, 2022

Related U.S. Application Data
(60) Provisional application No. 63/238,915, filed on Aug. 31, 2021.
(60) Provisional application No. 63/230,328, filed on Aug. 6, 2021.

(51) Int. Cl. H05K 7/20; H05K 7/18

(52) U.S. Cl. CPC H05K 7/20145; H05K 7/186

(57) ABSTRACT

Rack mounting adapters with airflow management are disclosed. In one embodiment, rack mounting adapter apparatus comprises: a housing configured to adapt an electrical component chassis subrack configured for side-to-side airflow cooling to mount to an equipment rack; and an airflow management system within the housing that converts the side-to-side airflow cooling of the electrical component chassis subrack to a front-to-back airflow configuration that intakes air from a front of the equipment rack and exhausts air to a back of the equipment rack.

### CROSS-REFERENCE TO RELATED APPLICATIONS

This application claims priority to U.S. Provisional Application No. 63/230,328 filed on Aug. 6, 2021, and titled “RACK MOUNTING ADAPTER WITH AIRFLOW MANAGEMENT,” and to U.S. Provisional Application No. 63/238,915 filed on Aug. 31, 2021, and titled “RACK MOUNTING ADAPTER WITH AIRFLOW MANAGEMENT,” the contents of both of which are hereby incorporated by reference in their entirety.

### BACKGROUND

Distributed Antenna Systems (DAS) are often used to improve the coverage of wireless base stations by extending the coverage area provided by the base station and for avoiding structures that contribute to penetration losses. The wireless service provided by the base stations can include commercial cellular service and/or private or public safety wireless communications. Today, elements of the DAS, such as the DAS head-end (also referred to as a DAS master unit), are often implemented by rack-mounted electronic components in a central office/data center. In many instances, the electronic components are mounted in open-frame racks and utilize side-to-side airflow to exhaust heat. However, in some central offices, racks are often placed in a row with adjacent racks. As a result, equipment in one rack may have its air intake aligned with the exhaust of adjacent equipment so that the air it intakes for the purpose of cooling is already above ambient. Further, the intake temperature of each succeeding rack will be higher as the air flows through successive racks.

### SUMMARY

Rack mounting adapters with airflow management are disclosed. In one embodiment, rack mounting adapter apparatus comprises: a housing configured to adapt an electrical component chassis subrack configured for side-to-side airflow cooling to mount to an equipment rack; and an airflow management system within the housing that converts the side-to-side airflow cooling of the electrical component chassis subrack to a front-to-back airflow configuration that intakes air from a front of the equipment rack and exhausts air to a back of the equipment rack.

### DRAWINGS

Embodiments of the present disclosure can be more easily understood and further advantages and uses thereof more readily apparent, when considered in view of the description of the preferred embodiments and the following figures.

FIG. 1 is a diagram illustrating an example rack mounting adapter with airflow management for use in combination with an electrical component chassis subrack.

FIG. 1A is a diagram of an example electrical component chassis subrack comprising side-to-side (in this example, left to right) airflow cooling.

FIGS. 1B, 1C and 1D are diagrams illustrating an example rack mounting adapter with airflow management for use in combination with the electrical component chassis subrack.

FIGS. 2 and 3 are diagrams of additional views of an example rack mounting adapter with airflow management for use in combination with an electrical component chassis subrack.

FIGS. 4A, 4B, and 4C are diagrams of alternate air diverter shapes.

FIG. 5 is a diagram of an alternate example rack mounting adapter with multiple air diverters for use in combination with an electrical component chassis subrack.

FIG. 6 is a diagram illustrating an example alternate rack mounting adapter with airflow management for use in combination with the electrical component chassis subrack.

FIGS. 7A and 7B are illustrations of an example rack mounting adapter with optional intake and exhaust port covers and/or fans.

FIGS. 8, 8A, 8B, and 8C are diagrams illustrating an example alternate rack mounting adapter with airflow management for use in combination with an electrical component chassis subrack.

FIGS. 9 and 9A are illustrations of example distributed antenna systems comprising at least one electrical component chassis subrack coupled to an equipment rack by a rack mounting adapter with airflow management embodiment.

In accordance with common practice, the various described features are not drawn to scale but are drawn to emphasize features relevant to the present disclosure. Reference characters denote like elements throughout figures and text.

### DETAILED DESCRIPTION

In the following detailed description, reference is made to the accompanying drawings that form a part hereof, and in which is shown by way of specific illustrative embodiments in which the embodiments may be practiced. These embodiments are described in sufficient detail to enable those skilled in the art to practice the embodiments, and it is to be understood that other embodiments may be utilized and that logical, mechanical, and electrical changes may be made without departing from the scope of the present disclosure. The following detailed description is, therefore, not to be taken in a limiting sense.

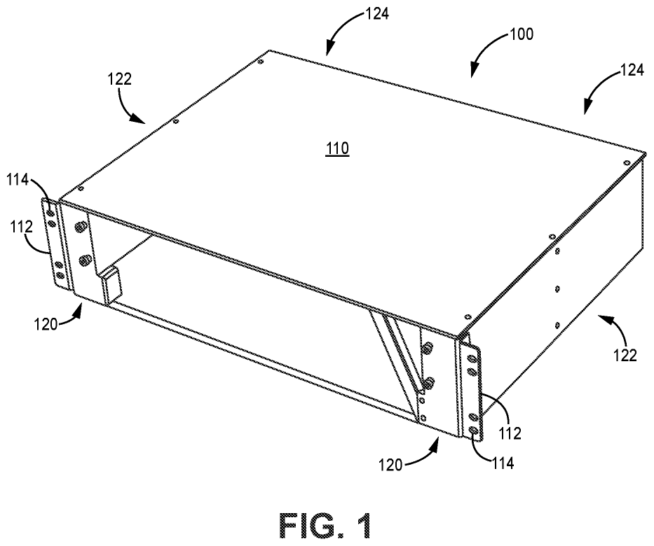

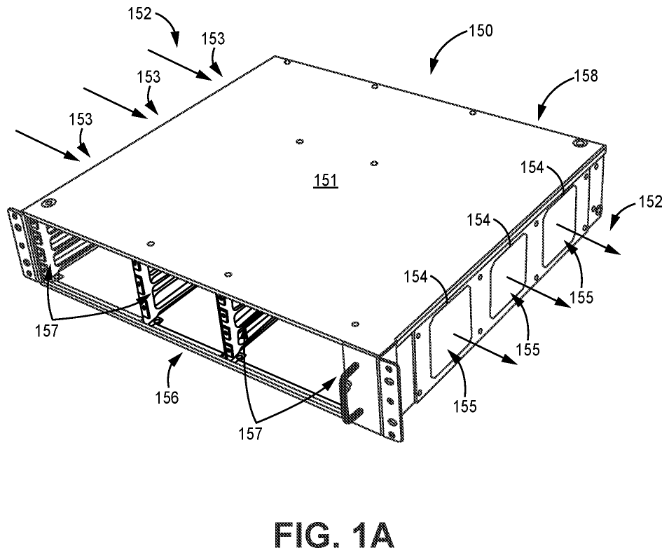

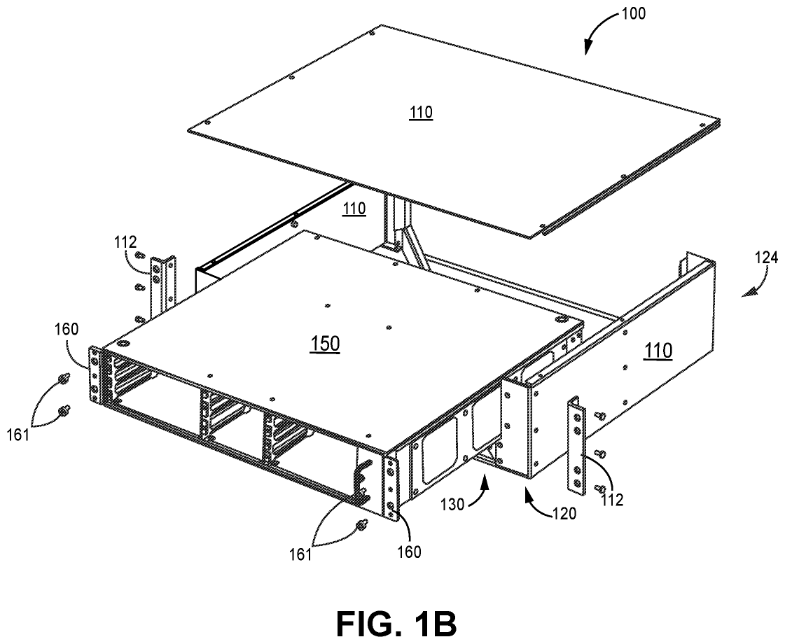

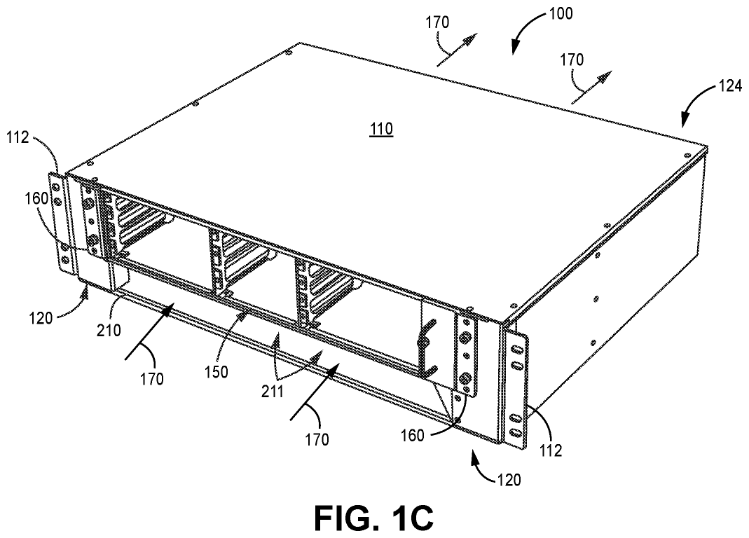

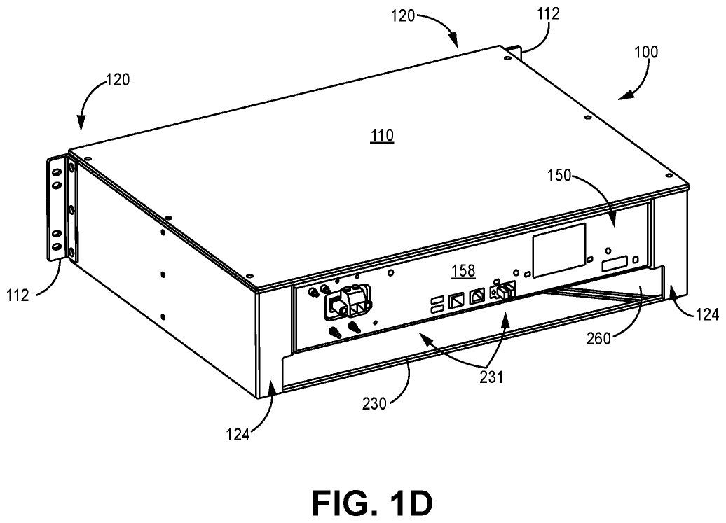

FIGS. 1, 2, and 3 are illustrations of an example rack mounting adapter 100 with airflow management for use in combination with the electrical component chassis subrack 150, as shown in FIG. 1A. The example electrical component chassis subrack 150 shown in FIG. 1A comprises side-to-side (in this example, left to right) airflow cooling shown at 152. In the illustrated example, the electrical component chassis subrack 150 is configured to receive a plurality of electronic circuit cards from a front 156 side of the subrack housing 151. Within the subrack housing 151, the plurality of electronic circuit cards is supported by a system of support rails 157. To facilitate the side-to-side airflow cooling 152, the subrack housing 151 includes intake side openings 153 and exhaust side openings 154 so that cooling air flows across the surfaces of the electronic circuit cards to remove heat generated by the electronic circuit cards from the subrack housing 151. In the particular example of FIG. 1A, the electrical component chassis subrack 150 is a 19-inch wide subrack. However, in other embodiments, the electrical component chassis subrack 150 may be larger or smaller than 19 inches. In some embodiments, the electrical component chassis subrack 150 may comprise fans 155 on one side or the other to motivate the side-to-side airflow cooling 152 by pushing or pulling air through the electrical component chassis subrack 150.

The rack mounting adapter 100 comprises an adapter housing 110 that serves as a coupler to facilitate mounting the electrical component chassis subrack 150 to an equipment rack having a larger rack size than supported by the native rack size of the electrical component chassis subrack 150. For example, where the electrical component chassis subrack 150 has a native rack size of 19 inches, the rack mounting adapter 100 facilitates mounting it to a larger rack size, such as a 23-inch, two-post or four-post open telecom equipment rack, for example. In this example, the electrical component chassis subrack 150 is size 2U high, while the rack mounting adapter 100 is size 3U high. To facilitate mounting of the rack mounting adapter 100 to the rack, the adapter housing 110 comprises mounting interfaces 112 that include one or more mounting holes 114 through which fasteners are inserted to fasten the adapter housing 110 to the rack. The mounting interfaces 112 may be shaped in the form of mounting ears or tabs and can be located at the front 120 of the adapter housing 110 for use with a four-post rack or at a midpoint position 122 for use with a two-post rack.

As shown in FIG. 1B, the electrical component chassis subrack 150 slides into a front side opening 130 of the rack mounting adapter 100, where it sits supported by the adapter housing 110. The electrical component chassis subrack 150, when installed into the adapter 100, is enclosed on the top, bottom, and sides by the adapter housing 110 of the rack mounting adapter 100. The electrical component chassis subrack 150 includes standard rack mounting hardware 160 that is used with screws or other fasteners 161 to secure the electrical component chassis subrack 150 in place onto the front 120 of the rack mounting adapter 100, as shown in FIG. 1C. When installed in this manner, the side-to-side airflow cooling 152, native to the electrical component chassis subrack 150, is effectively converted to front-to-back airflow cooling 170, as described below.

As shown in FIG. 1D, the rack mounting adapter 100 provides access to the back side 158 of the electrical component chassis subrack 150 to facilitate cabling connections. The back side 158 of the electrical component chassis subrack 150, which comprises one or more power and/or data cable interfaces, penetrates through the back 124 of the adapter housing 110, providing access to said power and/or data cable interfaces.

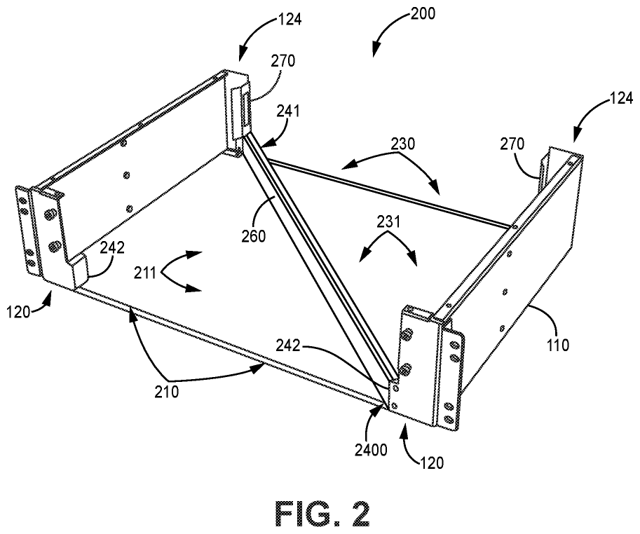

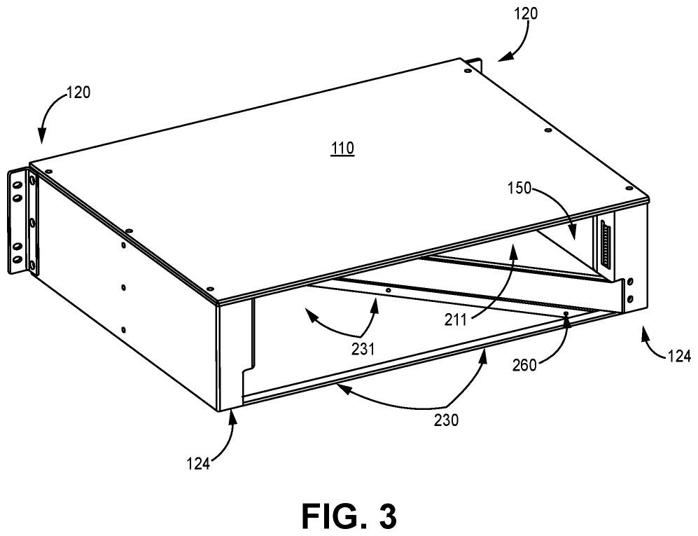

The rack mounting adapter 100 further comprises an airflow management system 200 illustrated in FIGS. 2-3 that adapts the side-to-side airflow cooling 152 configuration of the electrical component chassis subrack 150 to the front-to-back airflow cooling 170 configuration. With the electrical component chassis subrack 150 installed (as is shown in FIGS. 1C and 1D), the airflow management system 200 comprises a front side air intake port 210 that opens from the front 120 of the adapter housing 110 to an intake air plenum 211. The intake air plenum 211 is defined in part by a lower surface of the subrack housing 151 of the electrical component chassis subrack 150, the internal surfaces of the adapter housing 110, and an air diverter 260. The airflow management system 200 further comprises a back side air exhaust port 230 that opens to the back 124 of the adapter housing 110 and is coupled to an exhaust air plenum 231. The exhaust air plenum 231 is defined in part by the lower surface of the subrack housing 151 of the electrical component chassis subrack 150 and the internal surfaces of the adapter housing 110, and the air diverter 260. The air diverter 260 thus separates the intake air plenum 211 from the exhaust air plenum 231.

In some embodiments, the air diverter 260 is vertically (diagonally) oriented with respect to the air intake port 210 and air exhaust port 230 and extends from a first side 240 of the air intake port (for example, the right side as viewed looking into the air intake port 210) at the front 120 to the opposing side 241 at the air exhaust port 230 (for example the right side as viewed looking into the air exhaust port 230). The air diverter 260 channels the airflow received from the air intake port 210 into the intake air plenum 211 to the intake side openings 153 of the electrical component chassis subrack 150 side-to-side airflow cooling 152. That is, the intake air plenum 211 extends to the intake side openings 153 of the electrical component chassis subrack 150 side-to-side airflow cooling 152, providing a channel between the subrack side-to-side airflow cooling 152 and the air intake port 210. Airflow exiting the electrical component chassis subrack 150 side-to-side airflow cooling 152 is channeled into the exhaust air plenum 231 and out the air exhaust port 230. Here, the exhaust air plenum 231 extends to the exhaust side openings 154 of the electrical component chassis subrack 150 side-to-side airflow cooling 152, thus providing a channel between the subrack side-to-side airflow cooling 152 and the air exhaust port 230.

With this configuration, the side-to-side airflow cooling 152 through the electrical component chassis subrack 150 is approximately orthogonal to the front-to-back airflow cooling 170 entering the air intake port 210 and exiting the air exhaust port 230. In some embodiments, the air diverter 260 further serves as a structural support for the electrical component chassis subrack 150. The rack mounting adapter 100 may further comprise one or more support tabs (for example, as shown in FIG. 2 at 242) that extend into the ports and plenums to further support the electrical component chassis subrack 150 and assist in its installation.

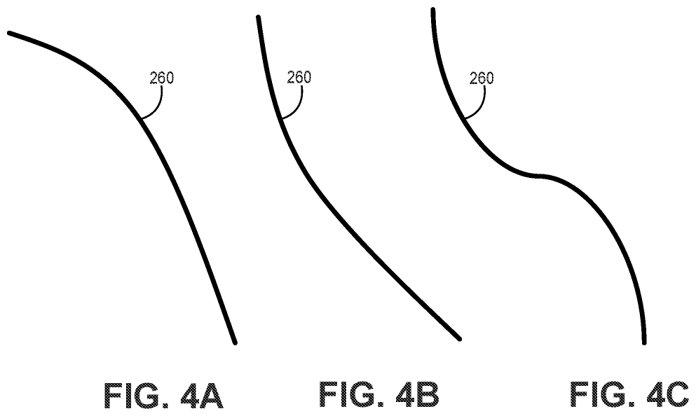

In FIGS. 2 and 3, the air diverter 260 is illustrated as being linear in shape. However, in other embodiments, other shapes may be used. For example, the air diverter 260 may be curved, either concave or convex (as shown in FIGS. 4A and 4B), or have a sinusoidal or “S”-shape (as shown in FIG. 4C) to tailor intake airflow direction or velocity differently at different points on the air diverter 260.

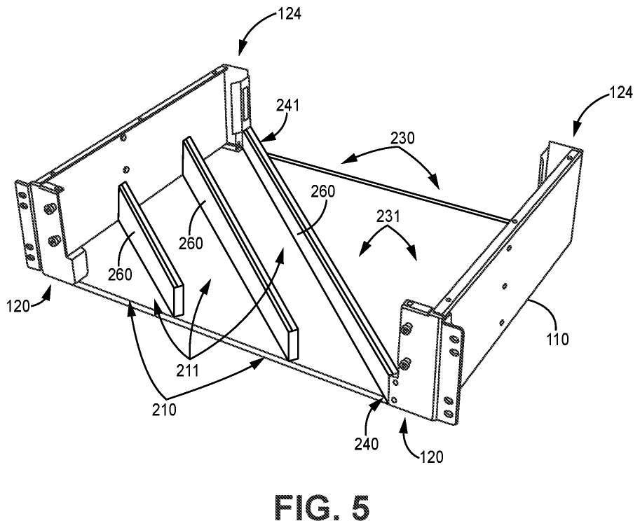

Moreover, in some embodiments, the intake air plenum 211 of the airflow management system may further comprise a plurality of air diverters 260 configured to channel airflow from the air intake port 210 to specific openings of the intake side openings 153 or fans 155 of the electrical component chassis subrack 150 as shown in FIG. 5.

In some embodiments, electrical continuity for grounding is provided by the rack mounting adapter 100 between the electrical component chassis subrack 150 and the rack to which the rack mounting adapter 100 is mounted. In some embodiments, the rack mounting adapter 100 comprises a zinc-plated steel or other metal material. As shown in FIG. 2, the rack mounting adapter 100 may comprise one or more grounding tabs 270 that include grounding features (e.g., copper finger stock) to provide a ground path to the back side of the electrical component chassis subrack 150 through the adapter housing 110 of the rack mounting adapter 100. The grounding tabs 270 may further guide the electrical component chassis subrack 150 as it slides into the rack mounting adapter 100 during installation.

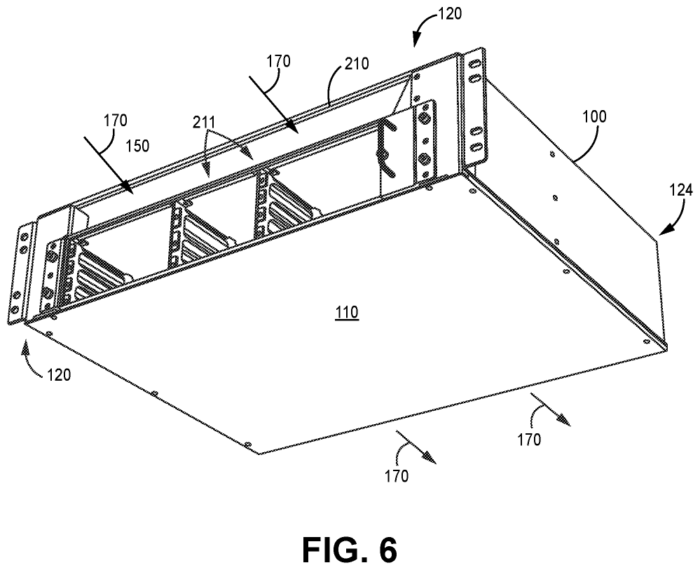

Although the air intake port 210 and air exhaust port 230 are shown in the figures above as being located beneath the electrical component chassis subrack 150 with the intake air plenum 211 channeling air through the side up to the intake side openings 153 of the electrical component chassis subrack 150, in other embodiments the air intake port 210 and air exhaust port 230 are instead positioned above the electrical component chassis subrack 150 as shown in FIG. 6 with the intake air plenum 211 channeling air through down the side of the adapter housing 110 to the intake side openings 153 of the electrical component chassis subrack 150.

In other embodiments, the rack mounting adapter 100 may comprise two airflow management systems, with a first, lower, airflow management system 200 positioned below the electrical component chassis subrack 150 channeling air through the side up to the electrical component chassis subrack (as shown in FIG. 1C), and a second, upper, airflow management system 200 above the electrical component chassis subrack 150 channeling air through the side down to the electrical component chassis subrack (as shown in FIG. 6). Such an embodiment may be used in conjunction with a 4U electrical component chassis subrack 150. In some such embodiments, the 4U electrical component chassis subrack 150 comprises two rows of fans 155 to motivate the side-to-side airflow cooling 152 through the subrack housing 151.

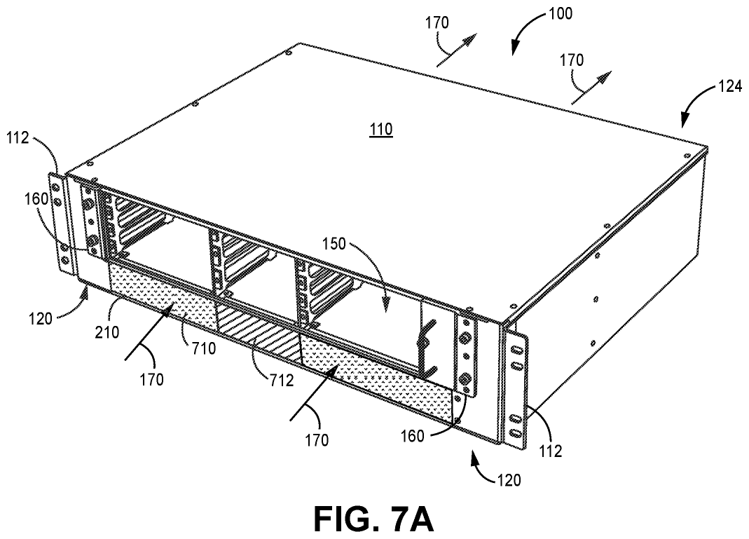

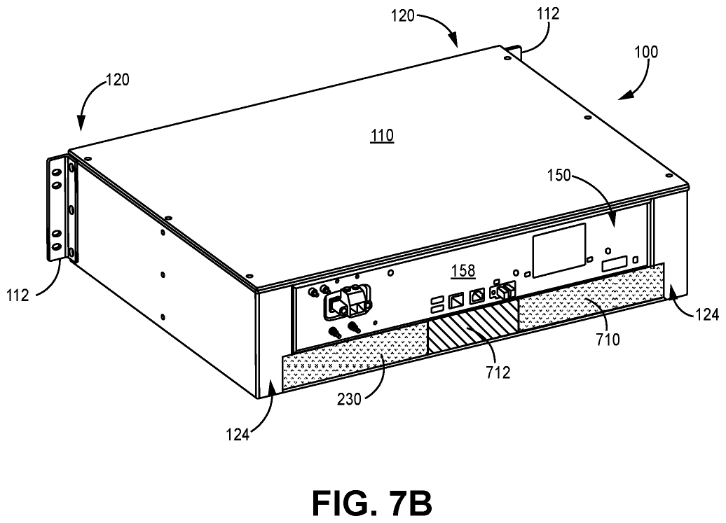

In some embodiments, as shown in FIGS. 7A and 7B, one or both of the air intake port 210 or the air exhaust port 230 may be optionally covered with a cover 710 (such as a grill cover or louvered cover, for example). The air intake port 210 and/or air exhaust port 230 may also comprise one or more optional fans 712 to motivate an airflow into the intake air plenum 211 and/or out from the exhaust air plenum 231. In some embodiments, the optional fans 712 may comprise 1U fans.

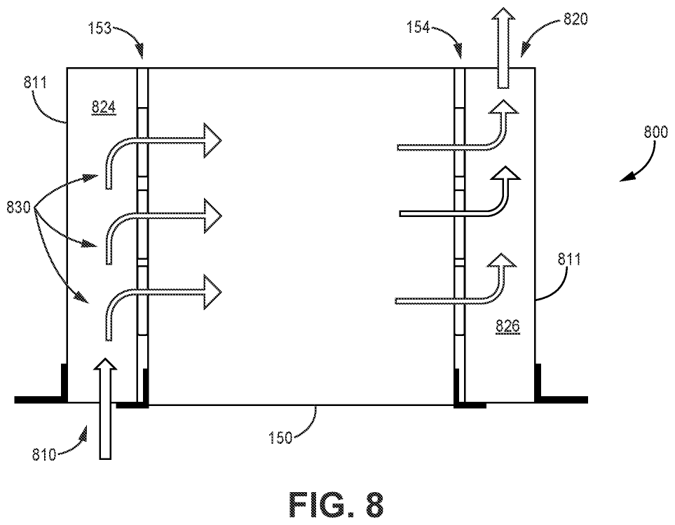

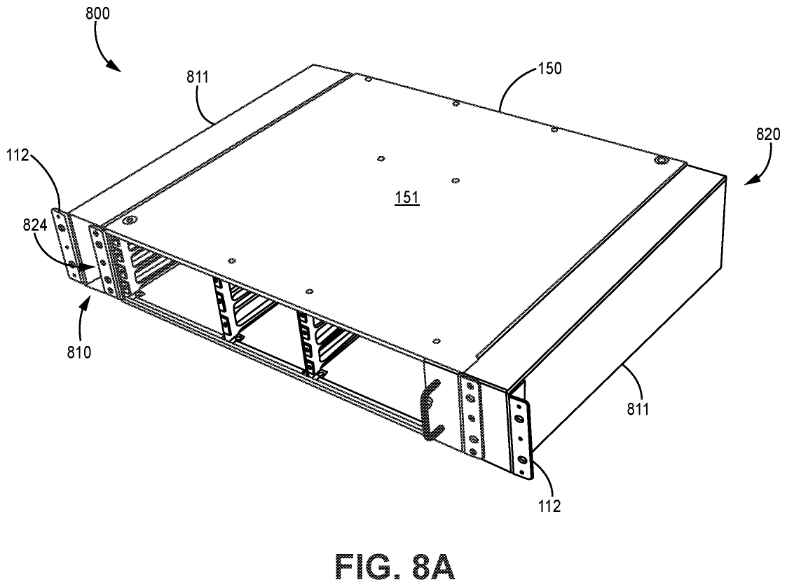

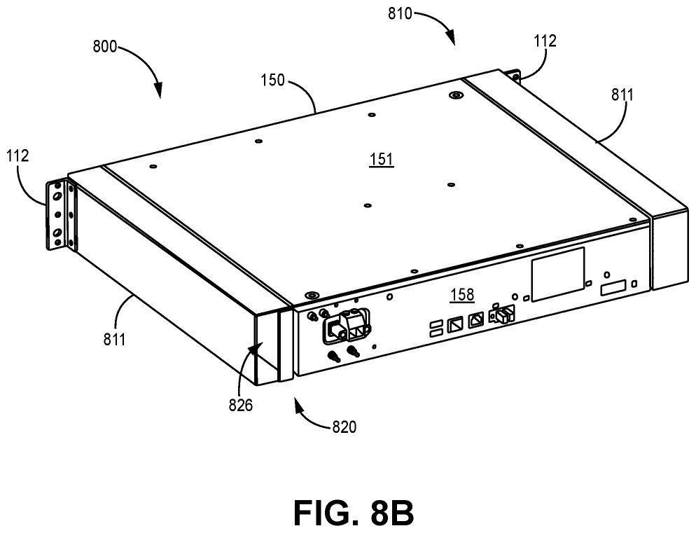

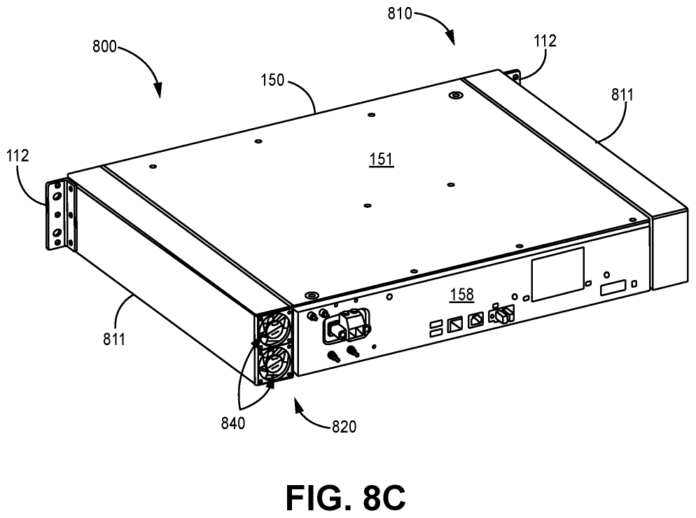

FIGS. 8 and 8A-8C illustrate an alternate example rack mounting adapter 800 with airflow management for use in combination with an electrical component chassis subrack such as the electrical component chassis subrack 150 of FIG. 1A. In this embodiment, the rack mounting adapter 800 has the same height as the native height of an electrical component chassis subrack 150. For example, if the electrical component chassis subrack 150 is a 2U subrack, then the rack mounting adapter 800 is also size 2U. In this embodiment, cavities 824 and 826 formed between the body 811 of the rack mounting adapter 800 and the subrack housing 151 of the electrical component chassis subrack 150 act as the intake and exhaust plenums. A front-side air intake port 810 opens to intake air plenum 824, and a back-side air exhaust port 820 opens to exhaust air plenum 826. The intake air plenum 824 channels airflow 830 received via the front-side air intake port 810 to the side-to-side airflow cooling intake side openings 153 of the electrical component chassis subrack 150. Air exiting the electrical component chassis subrack 150 exhausts from the exhaust side openings 154 into the exhaust air plenum 826 and out the back-side air exhaust port 820. It should be appreciated that such an embodiment may experience greater airflow resistance (as compared to the above-disclosed rack mounting adapter 100 embodiment) so that one or more fans 840 may be used at the air intake port and/or air exhaust port to increase the front-to-back airflow, as illustrated in FIG. 8C.

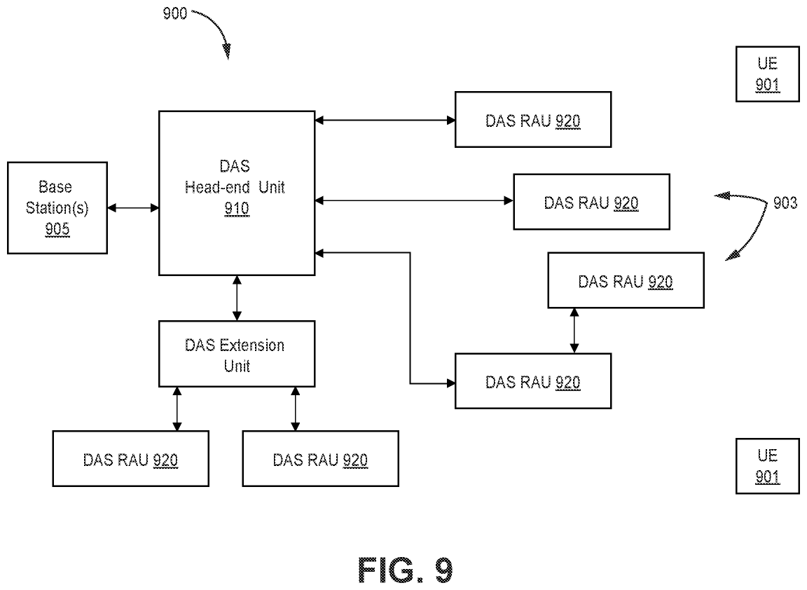

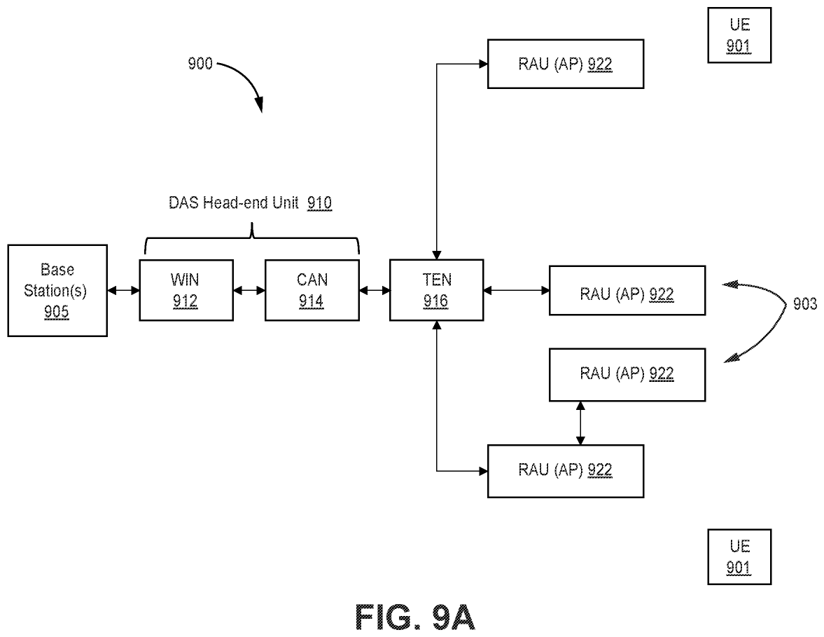

FIGS. 9 and 9A each illustrate example embodiments of a distributed antenna system (DAS) 900 comprising a DAS head-end unit 910 coupled to a plurality of remote antenna units 920. The head-end unit 910 may be located either on-premise or in a centralized RAN hub and, in some embodiments, takes RF and CPRI from service provider base stations and digitizes them for transport via fiber or copper cabling to the remote antenna units 920.

Each of the remote antenna units 920 can be communicatively coupled to the head-end unit 910 directly or indirectly via one or more other units (for example, via one or more intermediary units such as one or more extension or expansion nodes and/or via one or more other remote units, for example, using a daisy chain or ring topology).

The head-end unit 910 is configured to receive downlink radio frequency signals from one or more base stations 905, such as a centralized or cloud radio access network (C-RAN) hub. In the context of a fourth-generation (4G) Long Term Evolution (LTE) system, the base station 905 may also be referred to as an “evolved NodeB” or “eNodeB” and, in the context of a fifth-generation (5G) New Radio (NR) system, may also be referred to as a “gNodeB.” These signals from the base station 905 may also be referred to as “base station downlink signals.” Each base station downlink signal includes one or more radio frequency channels used for communicating in the downlink direction with user equipment 901 over a relevant wireless air interface. In the uplink direction, DAS 900 is configured to receive respective uplink radio frequency signals from the user equipment 901 within the coverage area 903 of the DAS 900, and transport those signals as “base station uplink signals” to the base stations 905.

Typically, each base station downlink signal is received at the head-end unit 910 from the one or more base stations 905 as analog radio frequency (RF) signals, though in some embodiments one or more of the base station signals are received in a digital form (for example, in a digital baseband form complying with the Common Public Radio Interface (“CPRI”) protocol, Open Radio Equipment Interface (“ORI”) protocol, the Open Base Station Standard Initiative (“OBSAI”) protocol, Open Radio Access Network (“ORAN”) protocol, or other protocol). The base station downlink signals may be digitized or otherwise formatted by the head-end unit 910 into a digital signal, and the resulting downlink transport signal is transported to the remote antenna unit 920, which radiate the downlink transport signals as wireless RF signals to user equipment 901 (UE, such as tablets or cellular telephone, for example) in the coverage area 903 of the DAS 900. In the uplink direction, a remote antenna unit 920 receives uplink RF signals from the user equipment 901, which may be digitized or otherwise formatted by the remote antenna unit 920 into a digital signal, and the resulting uplink transport signal is transported to the head-end unit 910 for transmission to the base station 905 as a base station uplink signal.

In some embodiments, the DAS 900 may be implemented as illustrated in FIG. 9A where the DAS comprises a wide-area integration node (WIN) 912, a central area node (CAN) 914, a transport extension node (TEN) 916, and a plurality of wireless access points 922. The WIN 912 and CAN 914 operate in conjunction with each other to implement the DAS head-end unit 910 that establishes communications with the one or more base stations 905. In this DAS architecture, the plurality of access points 922 defines the remote antenna units 920 of the DAS 900 which establish wireless connectivity with the user equipment 901 located within the coverage area 903.

In some embodiments, one or more rack mounting adapters with airflow management as discussed above are deployed to house one or more chassis subracks comprising electronics for implementing components of the DAS head-end unit 910. Such electronics may include, for example, but are not limited to, card-mounted circuitry, power supplies, signal processors, and/or wireless communications switch electronics. In some embodiments, such chassis subracks comprise a 19-inch chassis that is adapted for installation onto a 23-inch two-post or four-post open telecom rack via a rack mounting adapter with airflow management as discussed herein.

Although one or more embodiments are described with respect to DAS implementations, it should be understood that other embodiments may include the rack mounting adapter apparatus with airflow management used in conjunction with an electrical component chassis subrack of any other type of wireless communication system (such as, but not limited to repeaters or base stations) or data networks.

### EXAMPLE EMBODIMENTS

Example 1 includes a rack mounting adapter apparatus, the apparatus comprising: a housing configured to adapt an electrical component chassis subrack configured for side-to-side airflow cooling to mount to an equipment rack; and an airflow management system within the housing that converts the side-to-side airflow cooling of the electrical component chassis subrack to a front-to-back airflow configuration that intakes air from a front of the equipment rack and exhausts air to a back of the equipment rack.

Example 2 includes the apparatus of Example 1, wherein the electrical component chassis subrack comprises a 19-inch wide chassis, and the housing adapts the electrical component chassis subrack to a 23-inch telecom equipment rack.

Example 3 includes the apparatus of any of Examples 1-2, wherein the housing is configured to receive and secure the electrical component chassis subrack within the housing.

Example 4 includes the apparatus of Example 3, wherein the airflow management system comprises: a front-side air intake port that opens to an intake air plenum; and a back-side air exhaust port coupled to an exhaust air plenum.

Example 5 includes the apparatus of Example 4, wherein the intake air plenum is defined in part by a housing surface of the electrical component chassis subrack; and wherein the exhaust air plenum is defined in part by a housing surface of the electrical component chassis subrack.

Example 6 includes the apparatus of any of Examples 4-5, wherein the intake air plenum extends to the intake side of the electrical component chassis subrack side-to-side airflow cooling, providing a channel between the subrack side-to-side airflow cooling and the air intake port; and the exhaust air plenum extends to the exhaust side of the electrical component chassis subrack side-to-side airflow cooling, providing a channel between the subrack side-to-side airflow cooling and the air exhaust port.

Example 7 includes the apparatus of any of Examples 4-6, further comprising an air diverter that separates the intake air plenum from the exhaust air plenum; wherein the air diverter channels airflow received via the intake air plenum and channels it to an intake side of the electrical component chassis subrack side-to-side airflow cooling.

Example 8 includes the apparatus of Example 7, wherein the air diverter is diagonally oriented with respect to the air intake port and air exhaust port, and extends from a first side of the air intake port to an opposing side of the air exhaust port.

Example 9 includes the apparatus of any of Examples 7-8, wherein the air diverter has a shape that is at least in part one of: linear, curved, concave, convex, sinusoidal, or “S”-shaped.

Example 10 includes the apparatus of any of Examples 7-9, wherein the housing comprises mounting tabs located either at a front-side position for mounting with a four-post rack or at a midpoint position for mounting with a two-post rack.

Example 11 includes the apparatus of any of Examples 4-10, wherein one or both of the air intake port or the air exhaust port comprise a grill cover or louvered cover.

Example 12 includes the apparatus of any of Examples 4-11, wherein the air intake port comprises one or more fans to motivate an airflow into the intake air plenum.

Example 13 includes the apparatus of any of Examples 4-12, wherein the air exhaust port comprises one or more fans to motivate an airflow out from the exhaust air plenum.

Example 14 includes the apparatus of any of Examples 1-13, wherein the housing is configured for the component chassis subrack to slide into a front side opening of the housing; wherein the component chassis subrack is enclosed on a top, bottom, left, and right sides by the housing when installed.

Example 15 includes the apparatus of any of Examples 1-14, wherein the airflow management system comprises: a front-side air intake port that opens to an intake air plenum; and a back-side air exhaust port coupled to an exhaust air plenum; wherein the intake air plenum channels airflow received via the air intake port to an intake side of the electrical component chassis subrack side-to-side airflow cooling.

Example 16 includes the apparatus of any of Examples 1-15, wherein electrical continuity for grounding is provided by the rack mounting adapter between the electrical component chassis subrack and the equipment rack to which the rack mounting adapter is mounted.

Example 17 includes the apparatus of any of Examples 1-16, wherein the housing comprises one or more tabs that include grounding features to provide a ground path from a back-side of the electrical component chassis subrack to the equipment rack via the rack mounting adapter.

Example 18 includes the apparatus of any of Examples 1-17, wherein the airflow management system comprises a front-side air intake port that opens to an intake air plenum located either above or below the electrical component chassis subrack; and a back-side air intake port that opens to an exhaust air plenum located either above or below the electrical component chassis subrack.

Example 19 includes the apparatus of any of Examples 1-18, wherein the airflow management system comprises: a first front-side air intake port that opens to a first intake air plenum located above the electrical component chassis subrack; a second front-side air intake port that opens to a second intake air plenum located below the electrical component chassis subrack; a first back-side air intake port that opens to a first exhaust air plenum located above the electrical component chassis subrack; and a second back-side air intake port that opens to a second exhaust air plenum located below the electrical component chassis subrack.

Example 20 includes the apparatus of Example 19, the airflow management system further comprising: a first air diverter that separates the first intake air plenum from the first exhaust air plenum, wherein the first air diverter channels airflow received via the first intake air plenum and channels it to an intake side of the electrical component chassis subrack side-to-side airflow cooling; and a second air diverter that separates the second intake air plenum from the second exhaust air plenum, wherein the second air diverter channels airflow received via the second intake air plenum and channels it to the intake side of the electrical component chassis subrack side-to-side airflow cooling.

Example 21 includes a rack mounting adapter apparatus configured to adapt an electrical component chassis subrack configured for side-to-side airflow cooling to mount to an equipment rack, the rack mounting adapter apparatus further comprising: an airflow management system configured to convert the side-to-side airflow cooling of the electrical component chassis subrack to a front-to-back airflow configuration that intakes air from a front of the equipment rack and exhausts air to a back of the equipment rack.

Example 22 includes the rack mounting adapter apparatus of Example 21, wherein the airflow management system comprises: a front-side air intake port that opens to an intake air plenum; and a back-side air exhaust port coupled to an exhaust air plenum; wherein the intake air plenum channels airflow received via the air intake port to an intake side of the electrical component chassis subrack side-to-side airflow cooling.

Example 23 includes the rack mounting adapter apparatus of Example 22, wherein the front-side air intake port comprises one or more fans to motivate an airflow into the intake air plenum.

Example 24 includes the rack mounting adapter apparatus of any of Examples 22-23, wherein the back-side air exhaust port comprises one or more fans to motivate an airflow out from the exhaust air plenum.

Example 25 includes a system comprising: an equipment rack; a rack mounting adapter; and an electrical component chassis subrack configured for side-to-side airflow cooling, wherein the rack mounting adapter couples the electrical component chassis subrack to the equipment rack, wherein the rack mounting adapter comprises: an airflow management system configured to convert the side-to-side airflow cooling of the electrical component chassis subrack to a front-to-back airflow configuration that intakes air from a front of the equipment rack and exhausts air to a back of the equipment rack.

Example 26 includes the system of Example 25, wherein the equipment rack is part of at least one of: a head-end unit in a distributed antenna system; a wireless communication system; and a data network.

Example 27 includes the system of any of Examples 25-26, wherein the airflow management system comprises: a front-side air intake port that opens to an intake air plenum; and a back-side air exhaust port coupled to an exhaust air plenum; wherein the intake air plenum channels airflow received via the air intake port to an intake side of the electrical component chassis subrack side-to-side airflow cooling; wherein the front-side air intake port and the back-side air exhaust port comprises one or more fans to motivate airflow through at least one of the intake air plenum and the exhaust air plenum.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the presented embodiments. Therefore, it is manifestly intended that embodiments be limited only by the claims and the equivalents thereof.

What is claimed is:

1. A rack mounting adapter apparatus, the apparatus comprising:
a housing configured to adapt an electrical component chassis subrack configured for side-to-side airflow cooling to mount to an equipment rack; and
an airflow management system within the housing that converts the side-to-side airflow cooling of the electrical component chassis subrack to a front-to-back airflow configuration that intakes air from a front of the equipment rack and exhausts air to a back of the equipment rack.

2. The apparatus of claim 1, wherein the electrical component chassis subrack comprises a 19-inch wide chassis, and the housing adapts the electrical component chassis subrack to a 23-inch telecom equipment rack.

3. The apparatus of claim 1, wherein the housing is configured to receive and secure the electrical component chassis subrack within the housing.

4. The apparatus of claim 3, wherein the airflow management system comprises:
a front-side air intake port that opens to an intake air plenum; and
a back-side air exhaust port coupled to an exhaust air plenum.

5. The apparatus of claim 4, wherein the intake air plenum is defined in part by a housing surface of the electrical component chassis subrack; and
wherein the exhaust air plenum is defined in part by a housing surface of the electrical component chassis subrack.

6. The apparatus of claim 4, wherein the intake air plenum extends to the intake side of the electrical component chassis subrack side-to-side airflow cooling, providing a channel between the subrack side-to-side airflow cooling and the air intake port; and
the exhaust air plenum extends to the exhaust side of the electrical component chassis subrack side-to-side airflow cooling, providing a channel between the subrack side-to-side airflow cooling and the air exhaust port.

7. The apparatus of claim 4, further comprising an air diverter that separates the intake air plenum from the exhaust air plenum;
wherein the air diverter channels airflow received via the intake air plenum and channels it to an intake side of the electrical component chassis subrack side-to-side airflow cooling.

8. The apparatus of claim 7, wherein the air diverter is diagonally oriented with respect to the air intake port and air exhaust port, and extends from a first side of the air intake port to an opposing side of the air exhaust port.

9. The apparatus of claim 7, wherein the air diverter has a shape that is at least in part one of: linear, curved, concave, convex, sinusoidal, or “S”-shaped.

10. The apparatus of claim 7, wherein the housing comprises mounting tabs located either at a front-side position for mounting with a four-post rack or at a midpoint position for mounting with a two-post rack.

11. The apparatus of claim 4, wherein one or both of the air intake port or the air exhaust port comprise a grill cover or louvered cover.

12. The apparatus of claim 4, wherein the air intake port comprises one or more fans to motivate an airflow into the intake air plenum.

13. The apparatus of claim 4, wherein the air exhaust port comprises one or more fans to motivate an airflow out from the exhaust air plenum.

14. The apparatus of claim 1, wherein the housing is configured for the component chassis subrack to slide into a front side opening of the housing;
wherein the component chassis subrack is enclosed on a top, bottom, left, and right sides by the housing when installed.

15. The apparatus of claim 1, wherein the airflow management system comprises:
a front-side air intake port that opens to an intake air plenum; and
a back-side air exhaust port coupled to an exhaust air plenum;
wherein the intake air plenum channels airflow received via the air intake port to an intake side of the electrical component chassis subrack side-to-side airflow cooling.

16. The apparatus of claim 1, wherein electrical continuity for grounding is provided by the rack mounting adapter between the electrical component chassis subrack and the equipment rack to which the rack mounting adapter is mounted.

17. The apparatus of claim 1, wherein the housing comprises one or more tabs that include grounding features to provide a ground path from a back-side of the electrical component chassis subrack to the equipment rack via the rack mounting adapter.

18. The apparatus of claim 1, wherein the airflow management system comprises a front-side air intake port that opens to an intake air plenum located either above or below the electrical component chassis subrack; and
a back-side air intake port that opens to an exhaust air plenum located either above or below the electrical component chassis subrack.

19. The apparatus of claim 1, wherein the airflow management system comprises:
a first front-side air intake port that opens to a first intake air plenum located above the electrical component chassis subrack;
a second front-side air intake port that opens to a second intake air plenum located below the electrical component chassis subrack;
a first back-side air intake port that opens to a first exhaust air plenum located above the electrical component chassis subrack; and
a second back-side air intake port that opens to a second exhaust air plenum located below the electrical component chassis subrack.

20. The apparatus of claim 19, the airflow management system further comprising:
a first air diverter that separates the first intake air plenum from the first exhaust air plenum, wherein the first air diverter channels airflow received via the first intake air plenum and channels it to an intake side of the electrical component chassis subrack side-to-side airflow cooling; and
a second air diverter that separates the second intake air plenum from the second exhaust air plenum, wherein the second air diverter channels airflow received via the second intake air plenum and channels it to the intake side of the electrical component chassis subrack side-to-side airflow cooling.

21. A rack mounting adapter apparatus configured to adapt an electrical component chassis subrack configured for side-to-side airflow cooling to mount to an equipment rack, the rack mounting adapter apparatus further comprising:
an airflow management system configured to convert the side-to-side airflow cooling of the electrical component chassis subrack to a front-to-back airflow configuration that intakes air from a front of the equipment rack and exhausts air to a back of the equipment rack.

22. The rack mounting adapter apparatus of claim 21, wherein the airflow management system comprises:
a front-side air intake port that opens to an intake air plenum; and
a back-side air exhaust port coupled to an exhaust air plenum;
wherein the intake air plenum channels airflow received via the air intake port to an intake side of the electrical component chassis subrack side-to-side airflow cooling.

23. The rack mounting adapter apparatus of claim 22, wherein the front-side air intake port comprises one or more fans to motivate an airflow into the intake air plenum.

24. The rack mounting adapter apparatus of claim 22, wherein the back-side air exhaust port comprises one or more fans to motivate an airflow out from the exhaust air plenum.

25. A system comprising:
an equipment rack;
a rack mounting adapter; and
an electrical component chassis subrack configured for side-to-side airflow cooling, wherein the rack mounting adapter couples the electrical component chassis subrack to the equipment rack, wherein the rack mounting adapter comprises:
an airflow management system configured to convert the side-to-side airflow cooling of the electrical component chassis subrack to a front-to-back airflow configuration that intakes air from a front of the equipment rack and exhausts air to a back of the equipment rack.

26. The system of claim 25, wherein the equipment rack is part of at least one of:
a head-end unit in a distributed antenna system;
a wireless communication system; and
a data network.

27. The system of claim 25, wherein the airflow management system comprises:
a front-side air intake port that opens to an intake air plenum; and
a back-side air exhaust port coupled to an exhaust air plenum;
wherein the intake air plenum channels airflow received via the air intake port to an intake side of the electrical component chassis subrack side-to-side airflow cooling;
wherein the front-side air intake port and the back-side air exhaust port comprises one or more fans to motivate airflow through at least one of the intake air plenum and the exhaust air plenum.
